(19) United States
(12) Patent Application Publication
(10) Pub. No.: US 2022/0014704 A1
(43) Pub. Date: Jan. 13, 2022

(54) IMAGING PROCESSING CIRCUIT, IMAGING SYSTEM, IMAGING PROCESSING METHOD, AND NON-TRANSITORY STORAGE MEDIUM

(71) Applicant: Panasonic Intellectual Property Management Co., Ltd., Osaka (JP)

(72) Inventor: Seiji YAMAHIRA, Kyoto (JP)

(21) Appl. No.: 17/484,549

(22) Filed: Sep. 24, 2021

Related U.S. Application Data
(63) Continuation of application No. PCT/JP2020/011475, filed on Mar. 16, 2020.

(30) Foreign Application Priority Data
Mar. 26, 2019 (JP) 2019-059467

(51) Int. Cl. H04N 5/3745; H01L 27/146; H01L 31/10

(52) U.S. Cl. CPC H04N 5/3745; H01L 31/10; H01L 27/14643

(57) ABSTRACT

An imaging processing circuit includes a restrictor (an offset circuit). The restrictor is configured to restrict at least one of a maximum value or a minimum value for an output signal from a photoelectric converter which is configured to convert a photon into an electric charge and whose conversion ratio from the photon to the electric charge is variable. The restrictor restricts a difference between the maximum value and the minimum value of the output signal from the photoelectric converter when the conversion ratio is a first conversion ratio to be smaller than a difference between the maximum value and the minimum value of the output signal from the photoelectric converter when the conversion ratio is a second conversion ratio. The second conversion ratio is less than the first conversion ratio.

### CROSS-REFERENCE TO RELATED APPLICATIONS

The present application is a Bypass Continuation of International Application No. PCT/JP2020/011475 filed on Mar. 16, 2020, which is based upon and claims the benefit of priority to Japanese Patent Application No. 2019-059467, filed on Mar. 26, 2019, the entire contents of both applications are incorporated herein by reference.

### TECHNICAL FIELD

The present disclosure relates generally to imaging processing circuits, imaging systems, imaging processing methods, and non-transitory storage media, and specifically to an imaging processing circuit used together with a photoelectric converter having a variable conversion ratio from a photon to an electric charge, an imaging system including the imaging processing circuit, an imaging processing method, and a non-transitory storage medium.

### BACKGROUND ART

A light detection device (an imaging system) including a photoelectric converter has been known (e.g., JP 2017-216459 A). The light detection device described in JP 2017-216459 A includes a plurality of unit pixel cells. Each unit pixel cell includes a photosensor, a signal detection circuit connected to a vertical signal line, an address transistor connected to the signal detection circuit, a capacitor, and a transfer transistor. The capacitor and the transfer transistor are connected between the photosensor and the address transistor. When the transfer transistor is turned on in a time period with the address transistor being off, electric charges of an amount reflecting the quantity of light incident on the photosensor in this time period are transferred to the capacitor. Then, the address transistor is turned on with the transfer transistor being off, and thereby, the electric charges are transferred via the transfer transistor, and a signal voltage (an output signal) corresponding to the amount of the electric charges accumulated in the capacitor is read to the vertical signal line.

### SUMMARY

It is an object of the present disclosure to provide an imaging processing circuit, an imaging system, an imaging processing method, and a non-transitory storage medium which increase the reading speed of an output signal.

An imaging processing circuit according to an aspect of the present disclosure includes a restrictor. The restrictor is configured to restrict at least one of a maximum value or a minimum value for an output signal from a photoelectric converter which is configured to convert a photon into an electric charge and whose conversion ratio from the photon to the electric charge is variable. The restrictor is configured to restrict a difference between the maximum value and the minimum value of the output signal from the photoelectric converter when the conversion ratio is a first conversion ratio to be smaller than a difference between the maximum value and the minimum value of the output signal from the photoelectric converter when the conversion ratio is a second conversion ratio. The second conversion ratio is less than the first conversion ratio.

An imaging system according to another aspect of the present disclosure includes: an imaging processing circuit including a restrictor configured to restrict at least one of a maximum value or a minimum value for an output signal from a photoelectric converter which is configured to convert a photon into an electric charge and whose conversion ratio from the photon to the electric charge is variable; and the photoelectric converter. The restrictor restricts a difference between the maximum value and the minimum value of the output signal from the photoelectric converter when the conversion ratio is a first conversion ratio to be smaller than a difference between the maximum value and the minimum value of the output signal from the photoelectric converter when the conversion ratio is a second conversion ratio less than the first conversion ratio.

An imaging processing method according to still another aspect of the present disclosure includes a restriction process. The restriction process includes restricting at least one of a maximum value or a minimum value for an output signal from a photoelectric converter which is configured to convert a photon into an electric charge and whose conversion ratio from the photon to the electric charge is variable. The restriction process includes restricting a difference between the maximum value and the minimum value of the output signal from the photoelectric converter when the conversion ratio is a first conversion ratio to be smaller than a difference between the maximum value and the minimum value of the output signal from the photoelectric converter when the conversion ratio is a second conversion ratio. The second conversion ratio is less than the first conversion ratio.

A non-transitory storage medium having stored thereon a program according to yet another aspect of the present disclosure is configured to cause one or more processors to execute the imaging processing method.

### BRIEF DESCRIPTION OF THE DRAWINGS

The figures depict one or more implementation in accordance with the present teaching, by way of example only, not by way of limitations. In the figures, like reference numerals refer to the same or similar elements.

FIG. 1 is a block diagram illustrating an imaging system according to an embodiment;

FIG. 2 is a time chart illustrating an operation example of the imaging system;

FIG. 3 is a block diagram illustrating an imaging system of a comparative example;

FIG. 4A is a time chart illustrating the operation example of the imaging system according to the embodiment;

FIG. 4B is a time chart illustrating an operation example of the imaging system according to the comparative example;

FIG. 5 is a block diagram illustrating a pixel circuit of an imaging system according to a first variation; and

FIG. 6 is a block diagram illustrating an offset circuit of an imaging system according to a second variation.

### DETAILED DESCRIPTION

An imaging processing circuit and an imaging system according to an embodiment will be described below with reference to the drawings. Note that the embodiment described below is a mere example of various embodiments of the present disclosure. Various modifications may be made to the following embodiment depending on design and the like as long as the object of the present disclosure is achieved.

### Schema

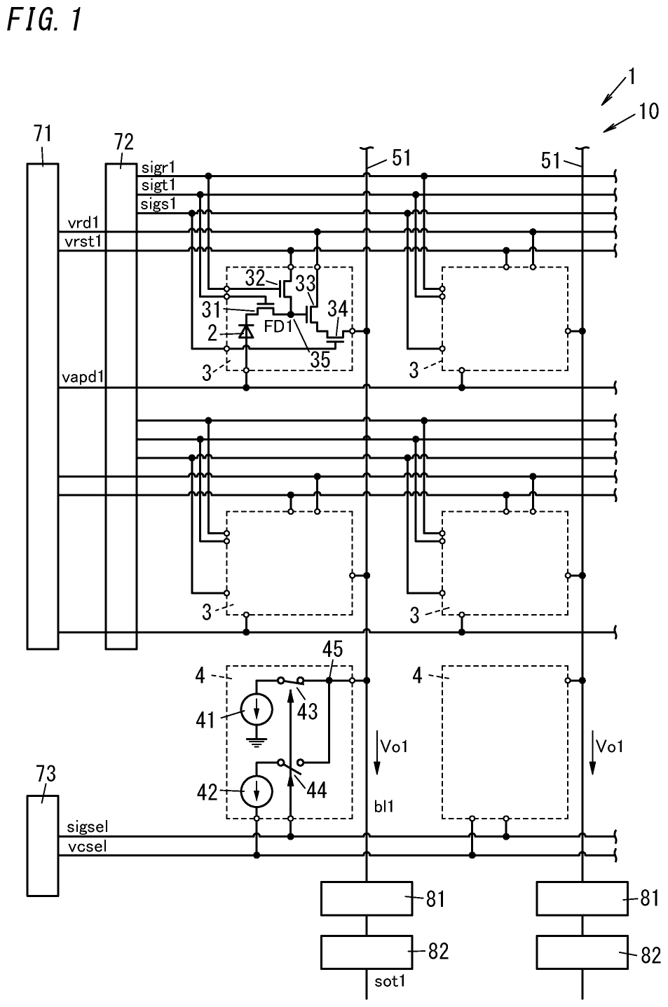

An imaging system 1 of the present embodiment is used as a two-dimensional image sensor such as a Charge Coupled Devices (CCD) image sensor or a Complementary Metal-Oxide Semiconductor (CMOS) image sensor. As illustrated in FIG. 1, the imaging system 1 includes a plurality of (in FIG. 1, four) pixel circuits 3, a plurality of (in FIG. 1, two) offset circuits 4, a plurality of (in FIG. 1, two) vertical signal lines 51, a voltage supply circuit 71, a vertical scan circuit 72, and an offset controller 73. The imaging system 1 further includes a plurality of (in FIG. 1, two) correlated double sampling circuits 81 and a plurality of (in FIG. 1, two) amplifier circuits 82. The imaging system 1 further includes a microcontroller configured to control overall operation of the imaging system 1.

The plurality of pixel circuits 3 are arranged in a two-dimensional array. Of the plurality of pixel circuits 3, two or more pixel circuits 3 belonging to the same column are electrically connected to a common vertical signal line 51. Each of the plurality of pixel circuits 3 includes a photoelectric converter 2. The photoelectric converter 2 converts a photon into an electric charge. The electric charge obtained by converting the photon by the photoelectric converter 2 is in the form of a voltage and is output as an output signal Vo1 to the vertical signal line 51. The output signal Vo1 is read to a device located outside the imaging system 1 via the vertical signal line 51.

The plurality of offset circuits 4 correspond to the plurality of vertical signal lines 51 on a one-to-one basis. Each offset circuit 4 is electrically connected to a corresponding one of the vertical signal lines 51. Each offset circuit 4 outputs an offset voltage to the corresponding one of the vertical signal lines 51. Thus, each offset circuit 4 restricts a minimum value of the output signal Vo1. In other words, the magnitude of the offset voltage output from the offset circuit 4 to the vertical signal line 51 determines the minimum value of the output signal Vo1.

An imaging processing circuit 10 includes at least one offset circuit 4 (a restrictor). In the present embodiment, the imaging processing circuit 10 is a component including: components of each of the plurality of pixel circuits 3 except for the photoelectric converter 2; and the plurality of offset circuits 4. That is, the imaging system 1 includes the imaging processing circuit 10 and a plurality of photoelectric converters 2.

Each photoelectric converter 2 includes an Avalanche Photo Diode. In the present embodiment, each photoelectric converter 2 consists of an avalanche photodiode. Each photoelectric converter 2 has a variable conversion ratio from a photon into an electric charge. That is, when a reverse voltage greater than or equal to a prescribed value (an avalanche breakdown voltage) is applied to the avalanche photodiode, an avalanche breakdown phenomenon significantly increases the conversion ratio from the photon to the electric charge. That is, each photoelectric converter 2 has a function of multiplying the electric charge. Note that in the avalanche photodiode, conversion from a photon into an electric charge when the avalanche breakdown phenomenon is occurring is referred to as avalanche multiplication.

In the following description, the conversion ratio from the photon into the electric charge when the photoelectric converter 2 multiplies the electric charge is referred to as a first conversion ratio. Moreover, the conversion ratio from the photon into the electric charge when the photoelectric converter 2 does not multiply the electric charge is referred to as a second conversion ratio. That is, the conversion ratio from the photon into the electric charge by the photoelectric converter 2 is variable between the first conversion ratio and the second conversion ratio. The second conversion ratio is less than the first conversion ratio.

In the present embodiment, irradiation of the photoelectric converter 2 with light when the conversion ratio of the photoelectric converter 2 is the first conversion ratio reduces the output signal Vo1 to the minimum value restricted by the offset circuit 4 regardless of the intensity of the light. Moreover, when the photoelectric converter 2 is no longer irradiated with light, or when exposure of the photoelectric converter 2 to light is stopped, the output signal Vo1 increases to the maximum value restricted by an amplifying element 33 which will be described later.

When the conversion ratio of the photoelectric converter 2 is the first conversion ratio, the photoelectric converter 2 multiplies the electric charge, and therefore, light can be detected with high sensitivity. At this time, the presence or absence of light can be expressed by a binary value in accordance with the output signal Vo1. In contrast, when the conversion ratio of the photoelectric converter 2 is the second conversion ratio, the magnitude of the output signal Vo1 changes between the maximum value and the minimum value in accordance with the quantity of light incident on the photoelectric converter 2, and therefore, the quantity of the light incident on the photoelectric converter 2 can be measured in accordance with the output signal Vo1. That is, when the conversion ratio of the photoelectric converter 2 is the second conversion ratio, the quantity of the light can be expressed more finely than the binary value.

The offset circuit 4 (the restrictor) restricts at least one of the maximum value or the minimum value for the output signal Vo1 from the photoelectric converter 2. The offset circuit 4 adjusts a difference between the maximum value and the minimum value of the output signal Vo1 from the photoelectric converter 2 when the conversion ratio is the first conversion ratio to be smaller than a difference between the maximum value and the minimum value of the output signal Vo1 from the photoelectric converter 2 when the conversion ratio is a second conversion ratio. Specifically, the offset circuit 4 increases the offset voltage when the conversion ratio of the photoelectric converter 2 is the first conversion ratio to be greater than the offset voltage when the conversion ratio of the photoelectric converter 2 is the second conversion ratio. The minimum value of the output signal Vo1 output to the vertical signal line 51 equals the offset voltage. That is, the offset circuit 4 (the restrictor) restricts the offset voltage corresponding to the minimum value of the voltage of the vertical signal line 51. The offset circuit 4 (the restrictor) adjusts the offset voltage to increase the minimum value of the output signal Vo1 when the conversion ratio of the photoelectric converter 2 is the first conversion ratio to be greater than the minimum value of the output signal Vo1 when the conversion ratio is a second conversion ratio.

Thus, the offset circuit 4 (the restrictor) reduces the difference between the maximum value and the minimum value of the output signal Vo1 from the photoelectric converter 2 as the conversion ratio of the photoelectric converter 2 increases.

The minimum value of the output signal Vo1 from the photoelectric converter 2 is restricted in the vertical signal line 51. That is, when the output signal Vo1 is less than the minimum value (the offset voltage) of the voltage of the vertical signal line 51 restricted by the offset circuit 4, the magnitude of the electric charge output from the photoelectric converter 2 does not change, but the output signal Vo1 output to the vertical signal line 51 is increased to the minimum value.

Moreover, as described above, one offset circuit 4 (the restrictor) restricts at least one of the maximum value or the minimum value (in the present embodiment, only the minimum value) for each of the output signals Vo1 from two or more photoelectric converters 2. That is, each offset circuit 4 restricts the minimum value of each of the output signals Vo1 from the two or more photoelectric converters 2 electrically connected thereto via the vertical signal line 51. The present embodiment includes a plurality of units each including such an offset circuit 4 and two or more photoelectric converters 2. Each offset circuit 4 restricts at least one of a maximum value or a minimum value of a voltage of the vertical signal line 51, thereby restricting at least one of the maximum value or the minimum value of the output signal Vo1.

According to the imaging system 1 of the present embodiment, the difference between the maximum value and the minimum value of the output signal Vo1 is smaller when the conversion ratio of the photoelectric converter 2 is the first conversion ratio than when the conversion ratio of the photoelectric converter 2 is the second conversion ratio. Thus, a change amount when the output signal Vo1 changes from the maximum value or the minimum value as a starting point is small, and thus, a time required for the change is reduced. Moreover, also when the output signal Vo1 changes from the intermediate value between the maximum value and the minimum value to the maximum value or the minimum value, the change amount is small, and the time required for the change is thus reduced. This can consequently increase the reading speed of the output signal Vo1 when the conversion ratio of the photoelectric converter 2 is the first conversion ratio.

Moreover, a difference between the maximum value and the minimum value of the output signal Vo1 from the photoelectric converter 2 when of the conversion ratio of the photoelectric converter 2 is the second conversion ratio is greater than a difference between the maximum value and the minimum value of the output signal Vo1 from the photoelectric converter 2 when of the conversion ratio of the photoelectric converter 2 is the first conversion ratio. Thus, without reducing the gray levels of light measurable when the conversion ratio of the photoelectric converter 2 is the second conversion ratio, the reading speed of the output signal Vo1 when the conversion ratio is the first conversion ratio can be increased.

Moreover, when of the conversion ratio of the photoelectric converter 2 is the first conversion ratio, the difference between the maximum value and the minimum value of the output signal Vo1 is relatively small, and therefore, a current consumed by the imaging system 1 can be reduced.

Moreover, in the imaging system 1, the offset circuit 4, which is a circuit configured to restrict at least one of the maximum value or the minimum value for the output signal Vo1 from the photoelectric converter 2, is provided outside the pixel circuit 3. Thus, each pixel circuit 3 can be downsized as compared to the case where the circuit configured to restrict at least one of the maximum value or the minimum value for the output signal Vo1 is included in the pixel circuit 3.

A timing at which the offset circuit 4 restricts the maximum value or the minimum value of the output signal Vo1 from the photoelectric converter 2 is not limited to a timing exemplified in the present embodiment. For example, a method may be adopted in which the maximum value or the minimum value of the output signal Vo1 is restricted already from a certain time period before a timing at which a photon is input to the photoelectric converter 2 and the output signal Vo1 is read from the pixel circuit 3. Moreover, for example, in a method in which the pixel circuit 3 includes three transistors, namely, a reset element 32, the amplifying element 33, and a selection element 34, the maximum value or the minimum value of the output signal Vo1 may be restricted for a certain time period after the output signal Vo1 is read.

Moreover, in the present embodiment, the voltage value of the output signal Vo1, which is generated by incidence of light, of the photoelectric converter 2 is greater than an initial value, but, for example, when the pixel circuit 3 includes a P-type transistor, the voltage value of the output signal Vo1, which is generated by incidence of light, of the photoelectric converter 2 is smaller than the initial value. Also in this case, the difference between the maximum value and the minimum value of the output signal Vo1 from the pixel circuit 3 is effectively reduced by restricting the maximum value or the minimum value of the output signal Vo1.

### Configuration

The plurality of pixel circuits 3 are arranged in a two-dimensional array. Two or more pixel circuits 3 belonging to the same row are electrically connected via a feed wire to the voltage supply circuit 71. The two or more pixel circuits 3 belonging to the same row are electrically connected via a feed wire to the vertical scan circuit 72. A plurality of columns of the plurality of pixel circuits 3 correspond to the plurality of correlated double sampling circuits 81 on a one-to-one basis. Two or more pixel circuits 3 belonging to the same column are electrically connected via a feed wire to a common corresponding one of the correlated double sampling circuits 81. Each correlated double sampling circuit 81 is electrically connected to a corresponding one of the amplifier circuits 82.

One pixel circuit 3 of the plurality of pixel circuits 3 will be described below, unless otherwise mentioned.

The pixel circuit 3 includes the photoelectric converter 2, the transfer element 31, the reset element 32, the amplifying element 33, the selection element 34, and wires electrically connecting these elements to one another. The transfer element 31, the reset element 32, the amplifying element 33, and the selection element 34 are each a semiconductor switching element such as an n-channel Metal Oxide Semiconductor Field Effect Transistor (MOSFET).

The photoelectric converter 2 (the avalanche photodiode) has an anode electrically connected to the voltage supply circuit 71. The photoelectric converter 2 has a cathode electrically connected to a source terminal of the transfer element 31. The transfer element 31 has a drain terminal electrically connected via a node 35 to a source terminal of the reset element 32 and a gate terminal of the amplifying element 33. In this embodiment, the node 35 is a point on a wire included in the pixel circuit 3. The amplifying element 33 has a source terminal electrically connected to a drain terminal of the selection element 34. The selection element 34 has a source terminal electrically connected to the vertical signal line 51.

The voltage supply circuit 71 (an adjuster) has a first mode and a second mode as operation modes. The voltage supply circuit 71 applies a reverse voltage greater than or equal to the avalanche breakdown voltage to the photoelectric converter 2 in the first mode. Thus, the voltage supply circuit 71 adjusts the conversion ratio of the photoelectric converter 2 to the first conversion ratio in the first mode. That is, the voltage supply circuit 71 causes the photoelectric converter 2 to multiply an electric charge in the first mode. In contrast, the voltage supply circuit 71 applies a reverse voltage less than the avalanche breakdown voltage to the photoelectric converter 2 in the second mode. Thus, the voltage supply circuit 71 adjusts the conversion ratio of the photoelectric converter 2 to the second conversion ratio in the second mode. That is, changing the magnitude of the reverse voltage to be applied to the photoelectric converter 2 corresponds to switching of the operation modes of the voltage supply circuit 71.

The imaging system 1 can detect light with higher sensitivity in the first mode than in the second mode and can more finely measure the quantity of light in the second mode than in the first mode. That is, switching the operation modes of the voltage supply circuit 71 enables the imaging system 1 to be used for the two applications.

The vertical scan circuit 72 inputs a voltage signal to a gate terminal of each of the transfer element 31, the reset element 32, and the selection element 34. This switches on and off each of the transfer element 31, the reset element 32, and the selection element 34. When the transfer element 31 is switched on, the electric charge generated by the photoelectric converter 2 is transferred to the node 35. The voltage supply circuit 71 applies a reset voltage having a prescribed magnitude to a drain terminal of the reset element 32. When the reset element 32 is switched on, the voltage of the node 35 equals the reset voltage. That is, the voltage of the node 35 is reset. The voltage supply circuit 71 applies a power supply voltage to a drain terminal of the amplifying element 33. When the amplifying element 33 is switched on, the amplifying element 33 adjusts the voltage of the node 35 and outputs the voltage to the selection element 34. Specifically, the amplifying (adjustment) element 33 outputs, to the selection element 34, a voltage obtained by amplifying or attenuating the voltage of the node 35 or a voltage equal to the voltage of the node 35. When the selection element 34 is switched on, the voltage adjusted by the amplifying element 33 is output as the output signal Vo1 to the vertical signal line 51.

The maximum value of the output signal Vo1 output to the vertical signal line 51 is restricted by a drain voltage of the amplifying element 33. In other words, the magnitude of the drain voltage of the amplifying element 33 determines the maximum value of the output signal Vo1.

The offset circuit 4 includes a first direct current source 41, a second direct current source 42, a switching element 43, a switching element 44, and wires electrically connecting these elements to one another. The first direct current source 41 has a plus terminal electrically connected to ground. The first direct current source 41 has a minus terminal electrically connected via the switching element 43 and a connection point 45 to the vertical signal line 51. In this embodiment, the connection point 45 is a point on a wire included in the offset circuit 4. The second direct current source 42 has a plus terminal to which the offset controller 73 applies a voltage having a prescribed magnitude. The second direct current source 42 has a minus terminal electrically connected via the switching element 44 and the connection point 45 to the vertical signal line 51. The first direct current source 41 outputs the same magnitude of current as the second direct current source 42.

Each of the switching elements 43 and 44 is a semiconductor switching element such as an n-channel MOSFET. The switching elements 43 and 44 each have a gate terminal to which the offset controller 73 inputs a control signal. This switches on and off each of the switching elements 43 and 44.

In this embodiment, the switching element 43 receives the control signal output from the offset controller 73 as it is, and the switching element 44 receives a signal obtained by inverting the high level and the low level of the control signal. Thus, the offset controller 73 controls such that while one of the switching elements 43 and 44 is on, the other of the switching elements 43 and 44 is off. The offset voltage (substantially 0 V) of the vertical signal line 51 while the offset controller 73 controls such that the switching element 43 is off and the switching element 44 is on is less than the offset voltage while the offset controller 73 controls such that the switching element 43 is on and the switching element 44 is off. The difference between these offset voltages is equal to a voltage which the offset controller 73 applies to the second direct current source 42.

The offset circuit 4 (the restrictor) restricts at least one of the maximum value or the minimum value of the output signal Vo1 from the photoelectric converter 2 in accordance with the operation mode of the voltage supply circuit 71 (the adjuster). The offset circuit 4 of the present embodiment restricts the minimum value of the output signal Vo1 from the photoelectric converter 2. That is, while the operation mode of the voltage supply circuit 71 is the first mode, the offset controller 73 controls such that the switching element 43 is on and the switching element 44 is off. In contrast, while the operation mode of the voltage supply circuit 71 is the second mode, the offset controller 73 controls such that the switching element 43 is off and the switching element 44 is on. Thus, the offset circuit 4 adjusts such that the minimum value of the output signal Vo1 while the operation mode of the voltage supply circuit 71 is the first mode is greater than the minimum value of the output signal Vo1 while the operation mode of the voltage supply circuit 71 is the second mode.

### Operation Example

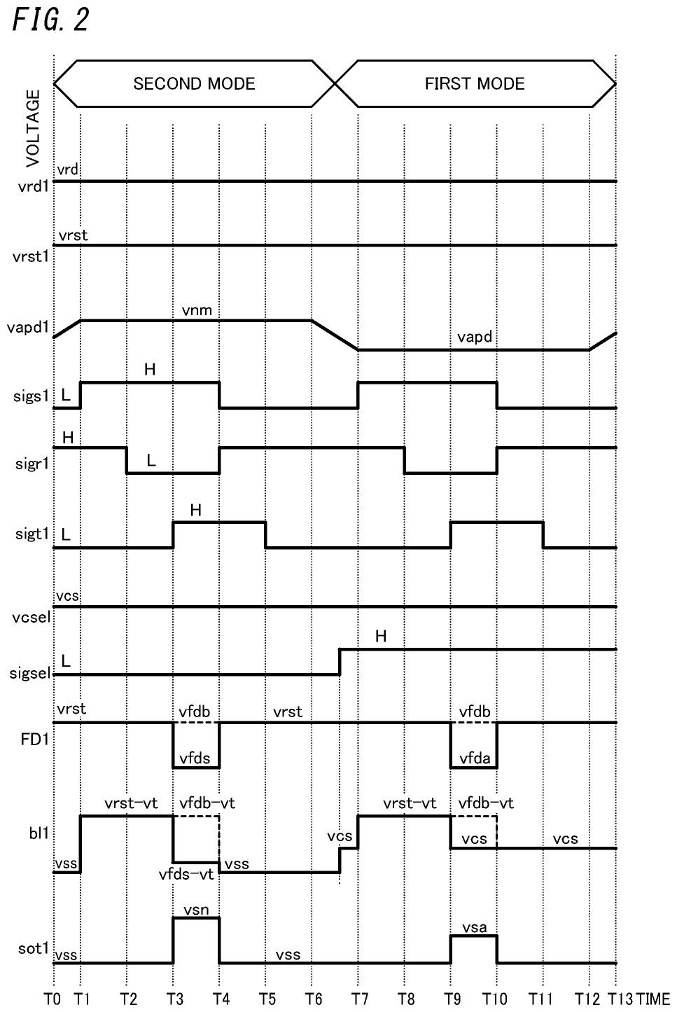

An operation example of the imaging system 1 will be described below with reference to FIG. 2. Symbols vrd1, vrst1, vapd1, sigs1, sigr1, sigt1, vcsel, sigsel, FD1, bl1, and sot1 provided at the left of the graph in FIG. 2 represent respective voltages at locations denoted by the same symbols in FIG. 1.

Description is given below provided that the operation mode of the voltage supply circuit 71 is switched between the first mode and the second mode at a constant cycle. Specifically, from time points T1 to T6, the voltage supply circuit 71 operates in the second mode, and from time points T7 to T12, the voltage supply circuit 71 operates in the first mode.

The imaging system 1 performs time-division reading of the output signals Vo1 from the plurality of pixel circuits 3. That is, from the plurality of pixel circuits 3 arranged in the two-dimensional array, the output signals Vo1 are output at different timings for each row. In this embodiment, description focusing on one pixel circuit 3 is given.

From the time points T1 to T6, a voltage (vapd1) applied to the photoelectric converter 2 has a negative value and is greater than a prescribed value corresponding to the avalanche breakdown voltage. In other words, from the time points T1 to T6, the reverse voltage applied to the photoelectric converter 2 is less than the avalanche breakdown voltage. Thus, the operation mode of the voltage supply circuit 71 is the second mode. Since the operation mode of the voltage supply circuit 71 is the second mode, the offset controller 73 outputs, to the offset circuit 4, a low level signal (sigsel) for controlling such that the switching element 43 is on and the switching element 44 is off. Thus, the voltage (bl1) of the vertical signal line 51 has a minimum value of “vss”. That is, the minimum value of the output signal Vo1 output from the pixel circuit 3 to the vertical signal line 51 is “vss”.

From the time points T1 to T2, the gate voltage (sigt1) of the transfer element 31 is at a low level, and therefore, electric charges generated by the photoelectric converter 2 are accumulated. Moreover, the gate voltage (sigr1) of the reset element 32 is at a high level, and therefore, the voltage (FD1) of the node 35 is fixed to a reset voltage (vrst). Moreover, the gate voltage (sigs1) of the selection element 34 is at the high level, and therefore, the reset voltage is output to the vertical signal line 51. Strictly speaking, the voltage (bl1) of the vertical signal line 51 has a value obtained by subtracting a threshold voltage vt between the gate and the source of the amplifying element 33 from the reset voltage (vrst). Note that the amplification factor of the amplifying element 33 is assumed to be 1. The voltage (bl1) of the vertical signal line 51 is input to the correlated double sampling circuit 81.

From the time points T2 to T3, the gate voltage (sigr1) of the reset element 32 is adjusted to a low level. Thereafter, from the time points T3 to T4, as the gate voltage (sigt1) of the transfer element 31 is at the high level, the electric charge generated by the photoelectric converter 2 is transferred to the node 35 and is output as the output signal Vo1 to the vertical signal line 51 via the amplifying element 33 and the selection element 34. Thus, when the photoelectric converter 2 is irradiated with light, the voltage (bl1) of the vertical signal line 51 has a value (indicated by a solid line from the time points T3 to T4 in FIG. 2) obtained by subtracting the threshold voltage vt from a voltage (vfds) of the node 35 according to the quantity of light with which the photoelectric converter 2 is irradiated. Moreover, when the photoelectric converter 2 is not irradiated with light, the voltage (bl1) of the vertical signal line 51 has a value (indicated by a broken line from the time points T3 to T4 in FIG. 2) obtained by subtracting the threshold voltage vt from a voltage (vfdb) corresponding to the dark current of the photoelectric converter 2.

The correlated double sampling circuit 81 calculates a difference voltage (vsn) between a voltage input from the vertical signal line 51 from the time points T1 to T2 and a voltage input from the vertical signal line 51 from the time points T3 to T4. As the quantity of light incident on the photoelectric converter 2 increases, the difference voltage (vsn) increases. Specifically, the difference voltage (vsn) is proportional to the quantity of light incident on the photoelectric converter 2.

The amplifier circuit 82 amplifies a signal (sot1) output from the correlated double sampling circuit 81. The signal (sot1) includes information on the difference voltage (vsn).

From the time points T4 to T5, the gate voltage (sigt1) of the transfer element 31 and the gate voltage (sigr1) of the reset element 32 are adjusted to the high level. Thus, the photoelectric converter 2 (the avalanche photodiode) is depleted. Thereafter, from the time point T5 to T6, the gate voltage (sigt1) of the transfer element 31 is adjusted to the low level.

From the time points T6 to T7, the voltage (vapd1) applied to the photoelectric converter 2 is reduced. As a result, from the time points T7 to T12, the voltage (vapd1) applied to the photoelectric converter 2 has a negative value and is less than a prescribed value corresponding to the avalanche breakdown voltage. In other words, from the time points T7 to T12, a reverse voltage applied to the photoelectric converter 2 is greater than the avalanche breakdown voltage. Thus, the operation mode of the voltage supply circuit 71 is the first mode. Since the operation mode of the voltage supply circuit 71 is the first mode, the offset controller 73 outputs, to the offset circuit 4, a high level signal (sigsel) for controlling such that the switching element 43 is off and the switching element 44 is on. Thus, the voltage (bl1) of the vertical signal line 51 has a minimum value of “vcs”. That is, the minimum value of the output signal Vo1 output from the pixel circuit 3 to the vertical signal line 51 is “vcs”. The “vcs” is greater than the “vss”, which is the minimum value of the voltage (bl1) of the vertical signal line 51 when the operation mode of the voltage supply circuit 71 is the second mode.

From the time points T7 to T12, the gate voltage of each of the transfer element 31, the reset element 32, and the selection element 34 is switched between the high level and the low level in a similar manner to from the time points T1 to T6. More details will be described below.

Operation from the time points T7 to T9 is the same as the operation from the time points T1 to T3, and the description thereof is omitted.

From the time points T9 to T10, the gate voltage (sigt1) of the transfer element 31 is at the high level, and therefore, the electric charge generated at the photoelectric converter 2 is transferred to the node 35 and is output as the output signal Vo1 to the vertical signal line 51 via the amplifying element 33 and the selection element 34, in a similar manner to the operation from the time points T3 to T4. Here, a reverse voltage greater than the avalanche breakdown voltage is applied to the photoelectric converter 2 (the avalanche photodiode), and therefore, when the photoelectric converter 2 is irradiated with light, the voltage (bl1) of the vertical signal line 51 has a minimum value (vcs) (indicated by a solid line from the time points T9 to T10 in FIG. 2) restricted by the offset circuit 4. Moreover, when the photoelectric converter 2 is not irradiated with light, the voltage (bl1) of the vertical signal line 51 has a value (indicated by a broken line from the time points T9 to T10 in FIG. 2) obtained by subtracting the threshold voltage vt from the voltage (vfdb) corresponding to the dark current of the photoelectric converter 2.

The correlated double sampling circuit 81 calculates a difference voltage (vsa) between a voltage input from the vertical signal line 51 from the time points T7 to T8 and a voltage input from the vertical signal line 51 from the time points T9 to T10. When light is incident on the photoelectric converter 2, the difference voltage (vsa) has a constant value defined by the voltage (vcsel) applied to the second direct current source 42 of the offset circuit 4 from the offset controller 73.

The amplifier circuit 82 amplifies a signal (sot1) output from the correlated double sampling circuit 81. The signal (sot1) includes information on the difference voltage (vsa).

Operation from the time points T10 to T12 is the same as the operation from the time points T4 to T6, and the description thereof is omitted.

From the time points T12 to T13, the voltage (vapd1) applied to the photoelectric converter 2 is increased. Thereafter, the operation returns to the time point T0. Before the time point T1, the negative voltage (vapd1) applied to the photoelectric converter 2 exceeds the prescribed value corresponding to the avalanche breakdown voltage. In other words, the reverse voltage applied to the photoelectric converter 2 is less than the avalanche breakdown voltage. Thus, the operation mode of the voltage supply circuit 71 is the second mode.

Note that here, description is given with reference to FIG. 2 and provided that the operation mode of the voltage supply circuit 71 is switched between the first mode and the second mode at the constant cycle, but the operation mode of the voltage supply circuit 71 may be fixed to the first mode. Moreover, the first mode or the second mode may be selected by externally giving an operation.

### Comparative Example

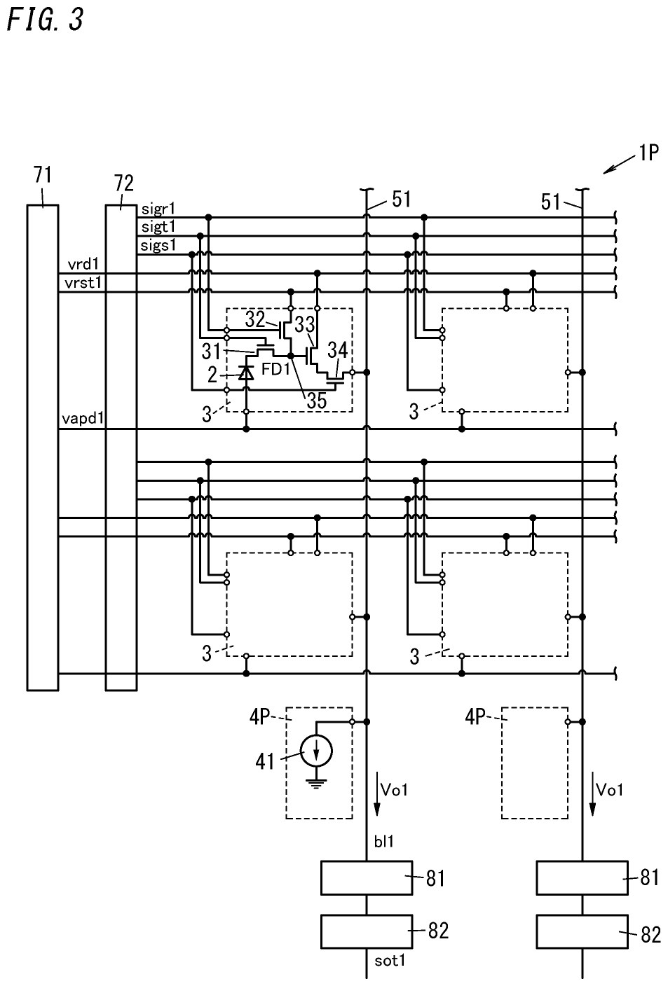

FIG. 3 shows a block diagram illustrating an imaging system 1P according to a comparative example. Components similar to those in the imaging system 1 of the embodiment are denoted by the same reference signs as those in the embodiment, and the description thereof will be omitted.

In the imaging system 1P, the configuration of an offset circuit 4P is different from that of the offset circuit 4 of the embodiment. That is, the offset circuit 4P includes only a first direct current source 41. Thus, an offset voltage output from the offset circuit 4P to a vertical signal line 51 is always constant.

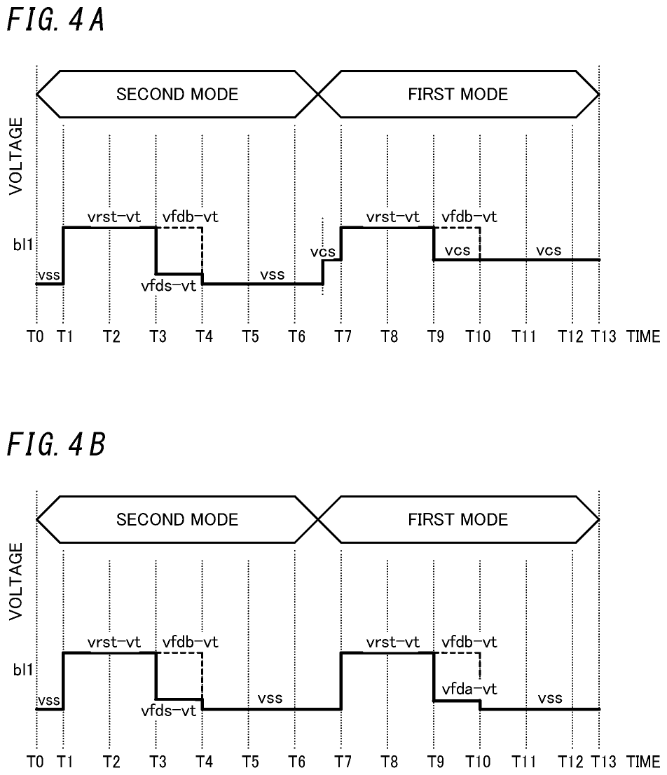

In FIG. 4A, part of FIG. 2 is shown again. In FIG. 4B, an operation example of the imaging system 1P according to the comparative example is shown. In the operation example shown in FIG. 4B, a gate voltage of each of a transfer element 31, a reset element 32, and a selection element 34 is switched between the high level and the low level at the same timing as that shown in FIG. 2 (the embodiment).

Referring to a time period from time points T7 to T13 in FIG. 4B, the voltage (bl1) of the vertical signal line 51 can change to a voltage (vss) lower than that in the case of FIG. 2 (FIG. 4A). As a result, referring to a time period from the time points T9 to T10, a minimum value of the output signal Vo1 output to the vertical signal line 51 has a value obtained by subtracting the threshold voltage vt from the voltage (vfda) corresponding to a saturated light intensity of the photoelectric converter 2. Here, the relationship vss<vfda−vt holds true.

In the imaging system 1 of the embodiment, when the photoelectric converter 2 multiplies the electric charge (in the first mode), the minimum value of the output signal Vo1 is restricted to a voltage higher than the “vss” as shown from the time points T9 to T10 in FIG. 2. Thus, a change amount when the output signal Vo1 changes to the minimum value is small, and thus, a time required for the change is reduced. As a result, the embodiment can increase the reading speed of the output signal Vo1 than the comparative example.

### First Variation

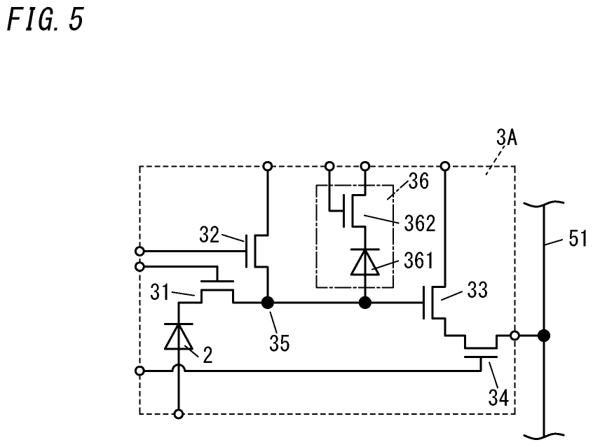

Next, a first variation of the embodiment will be described with reference to FIG. 5. Components similar to those in the embodiment are denoted by the same reference signs as those in the embodiment, and the description thereof will be omitted.

The first variation relates to the configuration of a pixel circuit 3A in place of the pixel circuit 3 of the embodiment. The pixel circuit 3A includes a clamp circuit 36 in addition to the components of the pixel circuit 3.

The clamp circuit 36 includes, for example, a diode 361 and a switching element 362. The switching element 362 is a semiconductor switching element such as an n-channel MOSFET. The diode 361 has an anode electrically connected to a node 35. The diode 361 has a cathode electrically connected to a source terminal of the switching element 362. The switching element 362 has a drain terminal to which a voltage supply circuit 71 applies a voltage. The switching element 362 has a gate terminal electrically connected to a vertical scan circuit 72.

When a control signal from the vertical scan circuit 72 changes a gate voltage to the high level to establish conduction between the drain and the source of the switching element 362, the voltage of the node 35 is clamped by a drain voltage of the switching element 362. In sum, a maximum value of the voltage of the node 35 is the sum of the drain voltage of the switching element 362 and a forward voltage of the diode 361. As a result, the maximum value of the output signal Vo1 output from the pixel circuit 3A to the vertical signal line 51 is restricted (clamped) by the clamp circuit 36. That is, when an electric charge output from a photoelectric converter 2 is satisfactorily great, a voltage according to the electric charge is reduced to the maximum value of the voltage of the node 35, thereby reducing the output signal Vo1.

When the gate voltage transitions to the low level, conduction is not established between the drain and the source of the switching element 362, and therefore, the voltage of the node 35 is no longer clamped.

The clamp circuit 36 (a restrictor) reduces, in accordance with the control signal from the vertical scan circuit 72, the maximum value of the output signal Vo1 when the conversion ratio of the photoelectric converter 2 is the first conversion ratio to be less than the maximum value of the output signal Vo1 when the conversion ratio is the second conversion ratio. When the operation mode of the voltage supply circuit 71 is the first mode, the clamp circuit 36 turns on the switching element 362. In contrast, when the operation mode of the voltage supply circuit 71 is the second mode, the clamp circuit 36 turns off the switching element 362. Thus, the clamp circuit 36 adjusts such that the maximum value of the output signal Vo1 while the operation mode of the voltage supply circuit 71 is the first mode is greater than the maximum value of the output signal Vo1 while the operation mode of the voltage supply circuit 71 is the second mode.

Restricting the maximum value of the output signal Vo1 when the operation mode of the voltage supply circuit 71 is the first mode and the conversion ratio of the photoelectric converter 2 is the first conversion ratio reduces the difference between the maximum value and the minimum value of the output signal Vo1. Thus, a change amount when the output signal Vo1 changes from the maximum value or the minimum value as a starting point is small, and thus, a time required for the change is reduced. Moreover, also when the output signal Vo1 changes from the intermediate value between the maximum value and the minimum value to the maximum value or the minimum value, the change amount is small, and thus, the time required for the change is reduced. This can consequently increase the reading speed of the output signal Vo1 when of the conversion ratio of the photoelectric converter 2 is the first conversion ratio.

Note that in the first variation, the magnitude of the offset voltage output from the offset circuit 4 to the vertical signal line 51 may be constant. That is, the offset circuit 4 has at least a first direct current source 41 as the comparative example shown in FIG. 3. At least one of the offset circuit 4 or the clamp circuit 36 controls at least one of the maximum value or the minimum value of the output signal Vo1 from the photoelectric converter 2. That is, in order to increase the reading speed of the output signal Vo1, at least one of the maximum value or the minimum value of the output signal Vo1 is restricted.

### Second Variation

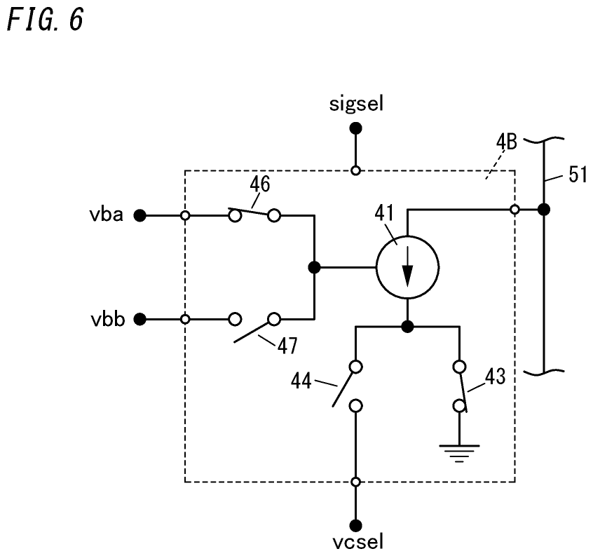

Next, a second variation of the embodiment will be described with reference to FIG. 6. Components similar to those in the embodiment are denoted by the same reference signs as those in the embodiment, and the description thereof will be omitted.

The second variation relates to the configuration of an offset circuit 4B in place of the offset circuit 4 of the embodiment. The offset circuit 4B includes a first direct current source 41 but does not include a second direct current source 42. The offset circuit 4B includes a switching element 43 and a switching element 44 in addition to the first direct current source 41. The offset circuit 4B changes the magnitude of an offset voltage to be output to a vertical signal line 51 by turning on and off of the switching elements 43 and 44.

The switching element 43 has a first end electrically connected to a plus terminal of the first direct current source 41. The switching element 43 has a second end electrically connected to ground. The switching element 44 has a first end electrically connected to the plus terminal of the first direct current source 41. The switching element 44 has a second end to which an offset controller 73 applies a voltage (vcsel) having a prescribed magnitude. The first direct current source 41 has a minus terminal electrically connected to the vertical signal line 51.

The offset controller 73 controls such that while one of the switching elements 43 and 44 is on, the other of the switching elements 43 and 44 is off. The offset voltage of the vertical signal line 51 while the offset controller 73 controls such that the switching element 43 is off and the switching element 44 is on is less than the offset voltage while the offset controller 73 controls such that the switching element 43 is on and the switching element 44 is off. The difference is equal to a voltage applied from the offset controller 73 to the second end of the switching element 44.

While the operation mode of a voltage supply circuit 71 is the first mode, the offset controller 73 controls such that the switching element 43 is off and the switching element 44 is off. In contrast, while the operation mode of the voltage supply circuit 71 is the second mode, the offset controller 73 controls such that the switching element 43 is off and the switching element 44 is on. Thus, the offset circuit 4B adjusts such that a minimum value of the output signal Vo1 while the operation mode of the voltage supply circuit 71 is the first mode is greater than the minimum value of the output signal Vo1 while the operation mode of the voltage supply circuit 71 is the second mode.

Moreover, the offset circuit 4B further includes a switching element 46 and a switching element 47. The offset circuit 4B is configured to change the magnitude of the offset voltage output to the vertical signal line 51 by at least one of switching on and off of the switching elements 43 and 44 or switching on and off of the switching elements 46 and 47.

When the switching element 46 is on and the switching element 47 is off, a first voltage (vba) is supplied via the switching element 46 to the first direct current source 41. Moreover, when the switching element 46 is off and the switching element 47 is on, a second voltage (vbb) is supplied via the switching element 47 to the first direct current source 41. The first direct current source 41 changes the magnitude of the output current in accordance with the magnitude of the voltage thus supplied, thereby changing the magnitude of the offset voltage output to the vertical signal line 51. Thus, the offset circuit 4B is configured to change the magnitude of the offset voltage in four ways based on a combination of on and off of the switching elements 43 and 44 and a combination of on and off of the switching elements 46 and 47.

According to the second variation, a component (the offset circuit 4B) in which the minimum value of the output signal Vo1 is adjustable is embodied without using the second direct current source 42.

### Other Variations of Embodiments

Other variations of the embodiment will be described below. The variations described below may be accordingly combined with each other.

Functions similar to those of the imaging system 1 may be implemented by an imaging processing method, a (computer) program, a non-transitory storage medium storing a program, or the like.

An imaging processing method according to one aspect includes a restriction process. The restriction process includes restricting at least one of a maximum value or a minimum value for an output signal Vo1 from a photoelectric converter 2 which is configured to convert a photon into an electric charge and whose conversion ratio from the photon to the electric charge is variable. The restriction process restricts a difference between the maximum value and the minimum value of the output signal Vo1 from the photoelectric converter 2 when the conversion ratio is a first conversion ratio to be smaller than a difference between the maximum value and the minimum value of the output signal Vo1 from the photoelectric converter 2 when the conversion ratio is a second conversion ratio. The second conversion ratio is less than the first conversion ratio.

A program according to one aspect is a program configured to cause one or more processor to execute the imaging processing method.

The imaging system 1 according to the present disclosure includes a computer system. The computer system includes, as principal hardware components, a processor and a memory. The functions of the imaging system 1 according to the present disclosure may be implemented by making the processor execute a program stored in the memory of the computer system. The program may be stored in the memory of the computer system in advance, may be provided via telecommunications network, or may be provided as a non-transitory recording medium such as a computer system-readable memory card, optical disc, or hard disk drive storing the program. The processor of the computer system may be made up of a single or a plurality of electronic circuits including a semiconductor integrated circuit (IC) or a largescale integrated circuit (LSI). The integrated circuit such as IC or LSI mentioned herein may be referred to in another way, depending on the degree of the integration and includes integrated circuits called system LSI, very-large-scale integration (VLSI), or ultra-large-scale integration (ULSI). Optionally, a field-programmable gate array (FPGA) to be programmed after an LSI has been fabricated or a reconfigurable logic device allowing the connections or circuit sections inside of an LSI to be reconfigured may also be adopted as the processor. The plurality of electronic circuits may be collected on one chip or may be distributed on a plurality of chips. The plurality of chips may be collected in one device or may be distributed in a plurality of devices. As mentioned herein, the computer system includes a microcontroller including one or more processors and one or more memories. Thus, the microcontroller is also composed of one or more electronic circuits including a semiconductor integrated circuit or a large-scale integrated circuit.

Moreover, collecting the plurality of functions of the imaging system 1 in one housing is not an essential configuration of the imaging system 1. The components of the imaging system 1 may be distributed in a plurality of housings. Moreover, at least some functions of the imaging system 1 may be realized by cloud (cloud computing) or the like.

In contrast, in the embodiment, at least some functions of the imaging system 1 distributed in a plurality of devices may be collected in one housing.

The photoelectric converter 2 is not limited to have the avalanche photodiode. The photoelectric converter 2 may include a combination of, for example, a multiplying element such as a Zener diode and a photoelectric conversion element such as a photodiode, a phototransistor, or a photoresistor.

The configuration of the photoelectric converter 2 is not limited to a configuration in which when an electric charge is multiplied, the output signal Vo1 varies between two values, but the configuration of the photoelectric converter 2 may be a configuration in which the output signal Vo1 varies among three or more values. For example, the photoelectric converter 2 may be configured such that when an electric charge is multiplied, the output signal Vo1 has a first value (maximum value) with no photon being incident, the output signal Vo1 has a second value with one photon being incident, and the output signal Vo1 has a third value (minimum value) with two or more photons being incident.

The photoelectric converter 2 is not limited to have a configuration in which the conversion ratio from a photon into an electric charge changes in two ways, namely, the first conversion ratio and the second conversion ratio, but the photoelectric converter 2 may have a configuration in which the conversion ratio changes in three or more ways. For example, a combination of a plurality of avalanche photodiodes may be used as the photoelectric converter 2 to implement a configuration in which the conversion ratio from a photon into an electric charge changes in three or more ways. The voltage supply circuit 71 (the adjuster) may have, in addition to the first mode and the second mode, one or more modes of changing the conversion ratio of the photoelectric converter 2 to a conversion ratio different from the first conversion ratio and from the second conversion ratio.

An element such as a capacitor configured to accumulate electric charges may be electrically connected to the node 35.

The plurality of pixel circuits 3 of the embodiment are aligned in rows and columns, but in each row and each column, the plurality of pixel circuits 3 do not have to be aligned in a straight line.

At least some components of the imaging system 1 may be provided on a semiconductor substrate or the like by a Micro Electro Mechanical Systems (MEMS) technique.

### Summary

The embodiment and the like described above discloses the following aspects.

An imaging processing circuit 10 of a first aspect includes a restrictor (an offset circuit 4, 4B, or a clamp circuit 36). The restrictor is configured to restrict at least one of a maximum value or a minimum value for an output signal Vo1 from a photoelectric converter 2 which is configured to convert a photon into an electric charge and whose conversion ratio from the photon to the electric charge is variable. The restrictor restricts a difference between the maximum value and the minimum value of the output signal Vo1 from the photoelectric converter 2 when the conversion ratio is a first conversion ratio to be smaller than a difference between the maximum value and the minimum value of the output signal Vo1 from the photoelectric converter 2 when the conversion ratio is a second conversion ratio. The second conversion ratio is less than the first conversion ratio.

With this configuration, a change speed when the output signal Vo1 from the photoelectric converter 2 changes is greater when the conversion ratio of the photoelectric converter 2 is the first conversion ratio than when the conversion ratio of the photoelectric converter 2 is the second conversion ratio. That is, the reading speed of the output signal Vo1 when the conversion ratio of the photoelectric converter 2 is the first conversion ratio is improved as compared to the case of a constant difference, regardless of the conversion ratio of the photoelectric converter 2, between the maximum value and the minimum value of the output signal Vo1 from the photoelectric converter 2.

In an imaging processing circuit 10 of a second aspect referring to the first aspect, the restrictor (offset circuit 4, 4B) includes at least one restrictor (offset circuit 4, 4B). The photoelectric converter 2 includes a plurality of photoelectric converters 2. One restrictor of the at least one restrictor restricts at least one of a maximum value or a minimum value for each of output signals Vo1 from two or more photoelectric converters 2 of the plurality of photoelectric converters 2.

With this configuration, the one restrictor (the offset circuit 4, 4B) restricts the output signals Vo1 from the two or more photoelectric converters 2, and therefore, the number of restrictors is reduced as compared to the case of individually providing a restrictor to each of the photoelectric converters 2.

In an imaging processing circuit 10 of a third aspect referring to the second aspect, the restrictor (the offset circuit 4, 4B) is configured to, regarding a unit of a vertical signal line 51 and the two or more photoelectric converters, which output output signals Vo1 to the vertical signal line 51, of the plurality of photoelectric converters 2, restrict at least one of a maximum value or a minimum value of a voltage of the vertical signal line 51.

With this configuration, the restrictor (the offset circuit 4, 4B) is configured to collectively restrict, in the vertical signal line 51, the output signals Vo1 output to the vertical signal line 51 from the two or more photoelectric converters 2.

In an imaging processing circuit 10 of a fourth aspect referring to any one of the first to third aspects, the restrictor (the offset circuit 4, 4B) is configured to adjust the minimum value of the output signal Vo1 from the photoelectric converter 2 when the conversion ratio is the first conversion ratio to be greater than the minimum value of the output signal Vo1 from the photoelectric converter 2 when the conversion ratio is the second conversion ratio.

This configuration increases the reading speed of the output signal Vo1 when the conversion ratio of the photoelectric converter 2 is the first conversion ratio.

In an imaging processing circuit 10 of a fifth aspect referring to any one of the first to fourth aspects, the restrictor (the clamp circuit 36) is configured to adjust the maximum value of the output signal Vo1 from the photoelectric converter 2 when the conversion ratio is the first conversion ratio to be less than the maximum value of the output signal Vo1 from the photoelectric converter 2 when the conversion ratio is the second conversion ratio.

This configuration increases the reading speed of the output signal Vo1 when the conversion ratio of the photoelectric converter 2 is the first conversion ratio.

In an imaging processing circuit 10 of a sixth aspect referring to any one of the first to fifth aspects, the restrictor (the offset circuit 4, 4B or the clamp circuit 36) is configured to reduce the difference between the maximum value and the minimum value of the output signal Vo1 from the photoelectric converter 2 as the conversion ratio increases.

This configuration improves the reading speed of the output signal Vo1 when the conversion ratio of the photoelectric converter 2 is relatively high.

An imaging processing circuit 10 of a seventh aspect referring to any one of the first to sixth aspects further includes an adjuster (a voltage supply circuit 71) configured to adjust the conversion ratio. The adjuster has, as operation modes, a first mode of adjusting the conversion ratio to the first conversion ratio and a second mode of adjusting the conversion ratio to the second conversion ratio. The restrictor (the offset circuit 4, 4B or the clamp circuit 36) is configured to restrict at least one of the maximum value or the minimum value of the output signal Vo1 from the photoelectric converter 2 in accordance with the operation mode of the adjuster.

With this configuration, the imaging processing circuit 10 detects light with higher sensitivity in the first mode than in the second mode and more finely measures the quantity of light in the second mode than in the first mode. That is, switching the operation modes of the voltage supply circuit 71 enables the imaging processing circuit 10 to be used in the two applications.

In an imaging processing circuit 10 of an eighth aspect referring to any one of the first to seventh aspects, the photoelectric converter 2 includes an avalanche photodiode. The first conversion ratio is a conversion ratio when an avalanche breakdown voltage is applied to the avalanche photodiode.

This configuration enables the change speed of the output signal Vo1 to be increased when an avalanche breakdown of the avalanche photodiode occurs.

The configurations other than the configuration of the first aspect are not essential configurations of the imaging processing circuit 10 and may accordingly be omitted.

An imaging system 1 of a ninth aspect includes the imaging processing circuit 10 of any one of the first to eighth aspects, and the photoelectric converter 2.

This configuration increases the reading speed of the output signal Vo1 when the conversion ratio of the photoelectric converter 2 is the first conversion ratio.

An imaging processing method according to a tenth aspect includes a restriction process. The restriction process includes restricting at least one of a maximum value or a minimum value for an output signal Vo1 from a photoelectric converter 2 which is configured to convert a photon into an electric charge and whose conversion ratio from the photon to the electric charge is variable. The restriction process includes restricting a difference between the maximum value and the minimum value of the output signal Vo1 from the photoelectric converter 2 when the conversion ratio is a first conversion ratio to be smaller than a difference between the maximum value and the minimum value of the output signal Vo1 from the photoelectric converter 2 when the conversion ratio is a second conversion ratio. The second conversion ratio is less than the first conversion ratio.

This configuration increases the reading speed of the output signal Vo1 when the conversion ratio of the photoelectric converter 2 is the first conversion ratio.

A program of an eleventh aspect is configured to cause one or more processor to execute the imaging processing method of the tenth aspect.

This configuration increases the reading speed of the output signal Vo1 when the conversion ratio of the photoelectric converter 2 is the first conversion ratio.

Various configurations (including the variations) of the imaging system 1 of the embodiment are not limited to the aspects described above and may be embodied by an imaging processing method and a program.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. An imaging processing circuit comprising a restrictor configured to restrict at least one of a maximum value or a minimum value for an output signal from a photoelectric converter which is configured to convert a photon into an electric charge and whose conversion ratio from the photon to the electric charge is variable,
the restrictor restricting a difference between the maximum value and the minimum value of the output signal from the photoelectric converter when the conversion ratio is a first conversion ratio to be smaller than a difference between the maximum value and the minimum value of the output signal from the photoelectric converter when the conversion ratio is a second conversion ratio less than the first conversion ratio.

2. The imaging processing circuit of claim 1, wherein
the restrictor includes at least one restrictor,
the photoelectric converter includes a plurality of photoelectric converters, and
one restrictor of the at least one restrictor restricts at least one of a maximum value or a minimum value for each of output signals of two or more photoelectric converters of the plurality of photoelectric converters.

3. The imaging processing circuit of claim 2, wherein
the restrictor is configured to, regarding a unit of a vertical signal line and the two or more photoelectric converters, which output output signals to the vertical signal line, of the plurality of photoelectric converters, restrict at least one of a maximum value or a minimum value of a voltage of the vertical signal line.

4. The imaging processing circuit of claim 1, wherein
the restrictor is configured to adjust the minimum value of the output signal from the photoelectric converter when the conversion ratio is the first conversion ratio to be greater than the minimum value of the output signal from the photoelectric converter when the conversion ratio is the second conversion ratio.

5. The imaging processing circuit of claim 1, wherein
the restrictor is configured to adjust the maximum value of the output signal from the photoelectric converter when the conversion ratio is the first conversion ratio to be less than the maximum value of the output signal from the photoelectric converter when the conversion ratio is the second conversion ratio.

6. The imaging processing circuit of claim 1 wherein
the restrictor is configured to reduce the difference between the maximum value and the minimum value of the output signal from the photoelectric converter as the conversion ratio increases.

7. The imaging processing circuit of claim 1, further comprising an adjuster configured to adjust the conversion ratio, wherein
the adjuster has, as operation modes, a first mode of adjusting the conversion ratio to the first conversion ratio and a second mode of adjusting the conversion ratio to the second conversion ratio, and
the restrictor is configured to restrict at least one of the maximum value or the minimum value of the output signal from the photoelectric converter in accordance with the operation mode of the adjuster.

8. The imaging processing circuit of claim 1, wherein
the photoelectric converter includes an avalanche photodiode, and
the first conversion ratio is a conversion ratio when an avalanche breakdown voltage is applied to the avalanche photodiode.

9. An imaging system, comprising:
an imaging processing circuit including a restrictor configured to restrict at least one of a maximum value or a minimum value for an output signal from a photoelectric converter which is configured to convert a photon into an electric charge and whose conversion ratio from the photon to the electric charge is variable, and
the photoelectric converter,
the restrictor restricting a difference between the maximum value and the minimum value of the output signal from the photoelectric converter when the conversion ratio is a first conversion ratio to be smaller than a difference between the maximum value and the minimum value of the output signal from the photoelectric converter when the conversion ratio is a second conversion ratio less than the first conversion ratio.

10. An imaging processing method comprising a restriction process of restricting at least one of a maximum value or a minimum value for an output signal from a photoelectric converter which is configured to convert a photon into an electric charge and whose conversion ratio from the photon to the electric charge is variable,
the restriction process including restricting a difference between the maximum value and the minimum value of the output signal from the photoelectric converter when the conversion ratio is a first conversion ratio to be smaller than a difference between the maximum value and the minimum value of the output signal from the photoelectric converter when the conversion ratio is a second conversion ratio less than the first conversion ratio.

11. A non-transitory storage medium having stored thereon a program configured to cause one or more processor to execute the imaging processing method of claim 10.
